(19) United States
(12) Patent Application Publication
(10) Pub. No.: US 2009/0058466 A1
(43) Pub. Date: Mar. 5, 2009

(54) DIFFERENTIAL PAIR CIRCUIT

(76) Inventors: Allan Joseph Parks, Westlake Village, CA (US); William Francis Johnston, Sunnyvale, CA (US)

Correspondence Address: FISH & RICHARDSON P.C., P.O. BOX 1022, MINNEAPOLIS, MN, 55440-1022, US

(21) Appl. No.: 11/848,859

(22) Filed: Aug. 31, 2007

(51) Int. Cl. H03H 11/00; H03K 5/00; H03L 5/00

(52) U.S. Cl. 327/1; 327/306; 327/524

(57) ABSTRACT

A differential pair circuit includes a first transistor having a first control terminal, a first input terminal, and a first output terminal; a second transistor having a second control terminal, a second input terminal, and a second output terminal, a first buffer stage including a third transistor having a third control terminal, a third input terminal, and a third output terminal; and a second buffer stage including a fourth transistor having a fourth control terminal, a fourth input terminal, and a fourth output terminal. The first output terminal and the second output terminal are electrically connected; the third output terminal and the first control terminal are electrically connected; the fourth output terminal and the second control terminal are electrically connected; the first input terminal and the fourth input terminal are electrically connected; and the second input terminal and the third input terminal are electrically connected.

### TECHNICAL FIELD

This patent application relates generally to a differential pair circuit.

### BACKGROUND

A differential pair circuit typically includes transistors, which are coupled at their emitters and at their collectors. The transistors are driven by input signals that are symmetric and out of phase (or one input signal may be static). The resulting output of the differential pair circuit switches in response to the input signals and, ideally, is also symmetric. However, in reality, unequal and/or non-linear transistor base-emitter capacitances adversely affect the symmetry of a differential pair output.

More specifically, in a differential pair circuit, a transistor that is “on” (conducting) has a relatively large emitter-base capacitance, whereas a transistor that is “off” (non-conducting) typically has a smaller emitter-base capacitance. These capacitances are charged during switching, which causes one transistor to react more quickly than the other. The result is an asymmetry in the differential pair output. This asymmetry typically manifests itself as rising signal edges that are slower and undershoot, and falling signal edges that are faster and overshoot.

### SUMMARY

This patent application describes a differential pair circuit and circuit applications for the differential pair circuit.

In one example, the differential pair circuit includes a first transistor having a first control terminal, a first input terminal, and a first output terminal; a second transistor having a second control terminal, a second input terminal, and a second output terminal, a first buffer stage including a third transistor having a third control terminal, a third input terminal, and a third output terminal; and a second buffer stage including a fourth transistor having a fourth control terminal, a fourth input terminal, and a fourth output terminal. The first output terminal and the second output terminal are electrically connected; the third output terminal and the first control terminal are electrically connected; the fourth output terminal and the second control terminal are electrically connected; the first input terminal and the fourth input terminal are electrically connected; and the second input terminal and the third input terminal are electrically connected. The transistors may be bipolar junction transistors, in which case each control terminal is a base, each input terminal is a collector, and each output terminal is an emitter. The differential pair circuit may also include one or more of the following features, either alone or in combination.

The differential pair circuit may include one or more circuit elements electrically connected between the first input terminal and the second input terminal. A capacitor may be electrically connected between the first input terminal and the second input terminal. The capacitor may have a capacitance that is adjustable.

A first current source may be electrically connected to the third output terminal, a second current source may be electrically connected to the fourth output terminal, and a third current source may be electrically connected to both the first output terminal and the second output terminal.

A first source may apply a first signal to the third control terminal, and a second source may apply a second signal the fourth control terminal. The first and second signals may comprise differential signals or a differential signal and a reference signal.

The first transistor may have a first control terminal-output terminal capacitance, and the second transistor may have a second control terminal-output terminal capacitance. When the first transistor is on and the second transistor is off, the first control terminal-output terminal capacitance may be larger than the second control terminal-output terminal capacitance. When the first transistor is off and the second transistor is on, the second control terminal-output terminal capacitance may be larger than the first control terminal-output terminal capacitance.

A least one reference voltage may be electrically connected to the first input terminal and to the second input terminal. One or more varactors may be electrically connected between the first input terminal and the second input terminal.

This patent application also describes circuitry comprising a first differential pair circuit and a second differential pair circuit electrically connected to the first differential pair circuit.

The first differential pair circuit comprises a first transistor having a first control terminal, a first input terminal, and a first output terminal; a second transistor having a second control terminal, a second input terminal, and a second output terminal; a third transistor having a third control terminal, a third input terminal, and a third output terminal; and a fourth transistor having a fourth control terminal, a fourth input terminal, and a fourth output terminal. The first output terminal and the second output terminal are electrically connected; the third output terminal and the first control terminal are electrically connected; the fourth output terminal and the second control terminal are electrically connected; the first input terminal and the fourth input terminal are electrically connected; and the second input terminal and the third input terminal are electrically connected.

The second differential pair circuit comprises a fifth transistor having a fifth control terminal, a fifth input terminal, and a fifth output terminal; a sixth transistor having a sixth control terminal, as sixth input terminal, and a sixth output terminal, a seventh transistor having a seventh control terminal, a seventh input terminal, and a seventh output terminal; an eighth transistor having an eighth control terminal, and an eighth input terminal, and an eighth output terminal. The fifth output terminal and the sixth output terminal are electrically connected; the seventh output terminal and the fifth control terminal are electrically connected; the eighth output terminal and the sixth control terminal are electrically connected; the fifth input terminal and the eighth input terminal are electrically connected; and the sixth input terminal and the seventh input terminal are electrically connected.

The foregoing circuitry may include one or more of the following features, either alone or in combination.

The first input terminal and the eighth control terminal may be electrically connected. The second input terminal and the seventh control terminal may be electrically connected.

A first capacitor may be electrically connected between the first input terminal and the second input terminal. A second capacitor may be electrically connected between the fifth input terminal and the sixth input terminal. At least one of the first capacitor and the second capacitor may have a capacitance that is adjustable.

A first set of one or more varactors may be electrically connected between the first input terminal and the second input terminal. A second set of one or more varactors may be electrically connected between the fifth input terminal and the sixth input terminal.

This patent application also describes a comparator comprising an output terminal, and a differential pair for comparing a first signal to a second signal to generate an output signal at the output terminal. The differential pair comprises a first transistor having a first control terminal, a first input terminal, and a first output terminal; a second transistor having a second control terminal, a second input terminal, and a second output terminal; a third transistor having a third control terminal, a third input terminal, and a third output terminal; and a fourth transistor having a fourth control terminal, a fourth input terminal, and a fourth output terminal. The first output terminal and the second output terminal are electrically connected; the third output terminal and the first control terminal are electrically connected; the fourth output terminal and the second control terminal are electrically connected; the first input terminal and the fourth input terminal are electrically connected; and the second input terminal and the third input terminal are electrically connected. The first signal is applied to the third control terminal and the second signal is applied to the fourth control terminal. The comparator may include one or more of the following features, either alone or in combination.

A voltage buffer may be used for receiving a first signal and for storing the first signal. An attenuator may be used for attenuating the first signal following output from the voltage buffer and prior to application to the one of the third control terminal and the fourth control terminal.

This patent application also describes automatic test equipment comprising circuitry to generate test signals to send to a device under test, and a comparator comprising a differential pair circuit as described herein. The comparator is configured to receive responses from the DUT to the test signals, and to compare the responses to one or more values in order to determine a state of operation of the DUT.

The details of one or more examples are set forth in the accompanying drawings and the description below. Further features, aspects, and advantages will become apparent from the description, the drawings, and the claims.

### DESCRIPTION OF THE DRAWINGS

FIG. 1 shows a differential pair circuit with input buffer stages.

FIG. 2 shows a differential pair circuit without input buffer stages.

FIG. 3 shows an output driver circuit containing a differential pair circuit.

FIG. 4 shows an adjustable delay circuit containing differential pair circuits.

FIG. 5 shows a ring oscillator circuit containing differential pair circuits.

FIG. 6 shows a comparator containing a differential pair circuit.

FIG. 7 shows automatic test equipment.

FIG. 8 shows circuitry included in the automatic test equipment.

Like reference numerals in different figures indicate like elements.

### DETAILED DESCRIPTION

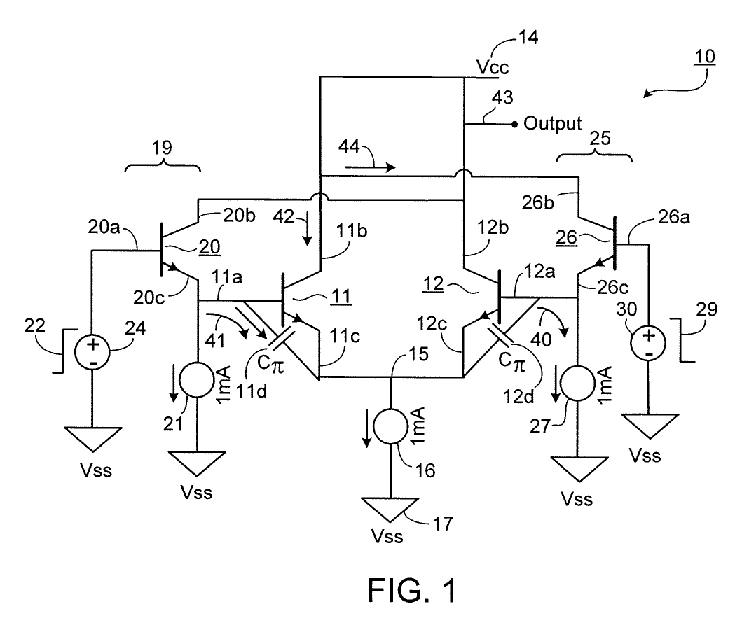

FIG. 1 shows an example of a differential pair circuit 10. Differential pair circuit 10 includes first transistor 11 and second transistor 12. Transistors 11 and 12 are bipolar junction transistors (BJTs) in FIG. 1.

First transistor 11 includes first base 11a, first collector 11b, and first emitter 11c, and second transistor 12 includes second base 12a, second collector 12b, and second emitter 12c. The base-emitter capacitances of transistor 11 and transistor 12 are represented in FIG. 1 by capacitors 11d and 12d, respectively. Separate capacitors are not actually present in the differential pair circuit; instead the capacitors represent the inherent capacitance of the base-emitter junctions. During operation, this capacitance in the first transistor is different from this capacitance in the second transistor since the “on” transistor's diffusion capacitance is larger than the “off” transistor's depletion capacitance. The capacitances also may be non-linear.

First collector 11b and second collector 12b are electrically connected to a reference voltage 14, V_{cc}, which may be, e.g., 5 volts (V). First emitter 11c is electrically connected to second emitter 12c at 15. In this application, electrical connection does not require a direct physical connection. Rather, an electrical connection may include intervening components between two components. Likewise, electrical connection may include non-wired electrical connections, such as those produced by a transformer. First emitter 11c and second emitter 12c are electrically connected to current source 16, which is one milliampere (mA) in this implementation. Current source 16 is electrically connected to a reference voltage 17, Vₛₛ, which may be ground or any other reference.

A first buffer stage 19 is electrically connected to the base 11a of first transistor 11. In this implementation, the first buffer stage includes a transistor connected in an emitter-follower configuration. The first buffer stage includes third transistor 20 having third base 20a, third collector 20b, and third emitter 20c. In other implementations, the first buffer stage may include additional circuitry, such as capacitors, resistors, transistors, and the like (not shown in FIG. 1). Third emitter 20c is electrically connected to first base 11a and to a current source 21, which is electrically connected to Vₛₛ. Third base 20a is driven by an input symmetric signal, which is represented by 22 in FIG. 1. FIG. 1 shows a voltage source 24 generating symmetric signal 22.

A second buffer stage 25 is electrically connected to the base 12a of second transistor 12. In this implementation, the second buffer stage includes a transistor connected in an emitter-follower configuration. The second buffer stage includes fourth transistor 26 having fourth base 26a, fourth collector 26b, and fourth emitter 26c. In other implementations, the second buffer stage may include additional circuitry (not shown in FIG. 1). Fourth emitter 26c is electrically connected to second base 12a and to a current source 27, which is electrically connected to Vₛₛ. Fourth base 26a is driven by an input symmetric signal, which is represented by 29 in FIG. 1. FIG. 1 shows a voltage source 30 generating symmetric signal 29. Symmetric signal 29 may be out of phase with symmetric signal 22 (as shown, signal 22 is rising and signal 29 is falling). In an alternative implementation, a static signal may be substituted for symmetric signal 22 or 29. For example, a static signal may be at a substantially constant third state that is somewhere in between a logic high level an a logic low level.

As shown in FIG. 1, third collector 20b is electrically connected to second collector 12b, and fourth collector 26b is electrically connected to first collector 11b. As explained below, this configuration can reduce asymmetry in the differential pair circuit output (e.g., make the rise and fall portions of the output waveform more symmetric).

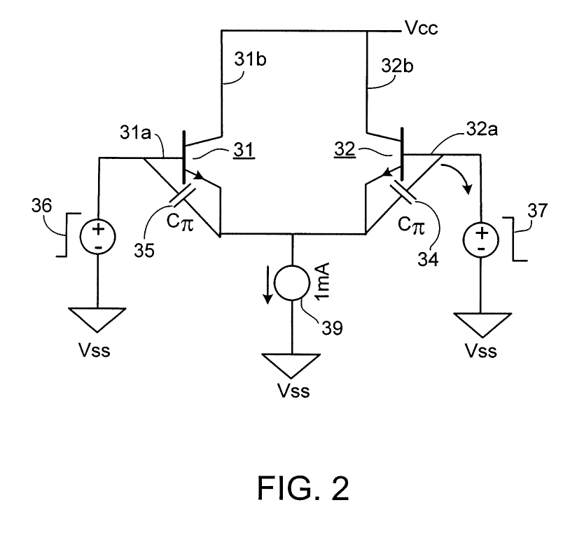

Referring to FIG. 2, we first describe what may occur in the absence of first buffer stage 19 and second buffer stage 25. Assume that first transistor 31 is off (e.g., non-conducting) and second transistor 32 is on (e.g., conducting). In this case, second transistor 32 has a relatively large base-emitter capacitance 34 (C_{π}) and first transistor 31 has a relatively small base-emitter capacitance 35 (at least smaller than that of second transistor 32). During switching, a logic high signal 36 is applied to first base 31a and a logic low signal is applied to second base 32a. As a result of the difference in parasitic emitter-base capacitances, more current flows out of second base 32a than into first base 31a. That is, the larger emitter-base capacitance 34 sources more current than the smaller emitter-base capacitance 35 sinks. This disrupts commutation of emitter biasing current (here, 1 mA from current source 39) from second transistor 32 to first transistor 31, which produces asymmetry in rising and falling waveforms at collectors 31b and 32b.

Incorporating the first and second buffer stages 19 and 25 into the differential pair circuit may alleviate the foregoing asymmetry to some extent. This is done, in part, by effectively recycling current output from the base of a transistor going from logic high to logic low into the collector of a transistor going from a logic low to a logic high.

More specifically, referring to FIG. 1, assume that the input to third base 20a is transitioning from logic low to logic high, and the input to fourth base 26a is transitioning from logic high to logic low. The logic high at third base 20a turns transistor 20 on, which causes current to flow to first base 11a, and which thereby causes the input to first base 11a to transition from logic low to logic high. In response, the emitter-base capacitance 11d of first transistor 11 charges. Meanwhile, the emitter-base capacitance 12d of second transistor 12 discharges.

Current 40 resulting from discharge of emitter-base capacitance 12d flows out of fourth base 26a and towards Vₛₛ (e.g., ground). This current partially satisfies the 1 mA pull-down current 27 required by fourth transistor 26. As a result, the amount of current 44 flowing through fourth collector 26b to fourth emitter 26c decreases, compensating for a corresponding increase in the amount of current 42 flowing through first collector 11b (due to current 40 being larger than current 41 through 11d). Currents through transistors 11 and 12 are therefore more balanced. As a result, there is less disruption, during switching, in the commutation of biasing current (16) from first transistor 11 to second transistor 12, which can lead to a reduction in asymmetry (e.g., an increase in symmetry) of rising and falling waveforms at collectors 11b and 12b. It is noted that the rising and falling waveforms at collectors 11b and 12b may be voltage waveforms measured across resistances (not shown) at the collectors.

The foregoing example describes the case where the input signal to third transistor 20 is transitioning from logic low to logic high, and the input signal to fourth transistor 26 is transitioning from logic high to logic low. In the opposite case, where the input signal to third transistor 20 is transitioning from logic high to logic low, and the input signal to fourth transistor 26 is transitioning from logic low to logic high, first transistor 11 behaves as does second transistor 12 above, second transistor 12 behaves as does first transistor 11 above, third transistor 20 behaves as does fourth transistor 26 above, and fourth transistor 26 behave as third transistor 20 does above.

The foregoing functionality of differential pair circuit 10 is similar in a case where one side of the differential pair circuit (e.g., third base 20a or fourth base 26a) receives a static voltage level (e.g., a logic level between logic high and logic low), while the other side transitions from logic low to logic high, or vice versa. In this case, the operation of differential pair circuit is essentially the same as above; however, differences in emitter-base capacitances may be less than in the example described above.

The differential pair circuit described herein has numerous applications. For example, the differential pair circuit may be used to implement a single-ended (SE) output driver having adjustable rise and fall times and having waveforms that are substantially symmetrical. For example the rising waveform and the falling waveforms have substantially the same shape (e.g., slope) for the reasons explained above.

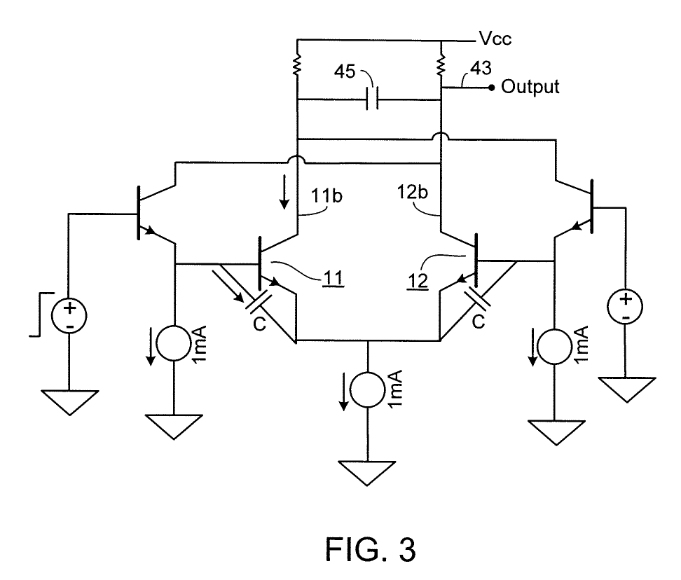

FIG. 3 shows an example of a single-ended output driver, which, e.g., outputs voltage at the output terminal 43. There, a capacitor 45 is electrically connected to both first collector 11b and second collector 12b. The capacitor may be adjustable to control the collector currents and thereby control the resulting output signal rise and fall times. Typically, the larger the capacitor is, the greater the rise and fall times are. Although a single capacitor is shown in FIG. 3, any number of capacitors and/or capacitive elements (e.g., elements that are not capacitors per se, but that have capacitance) may be used. In another implementation, one or more varactors (not shown) may be used in addition to, or in place of, the capacitor shown in FIG. 3 to implement the output driver.

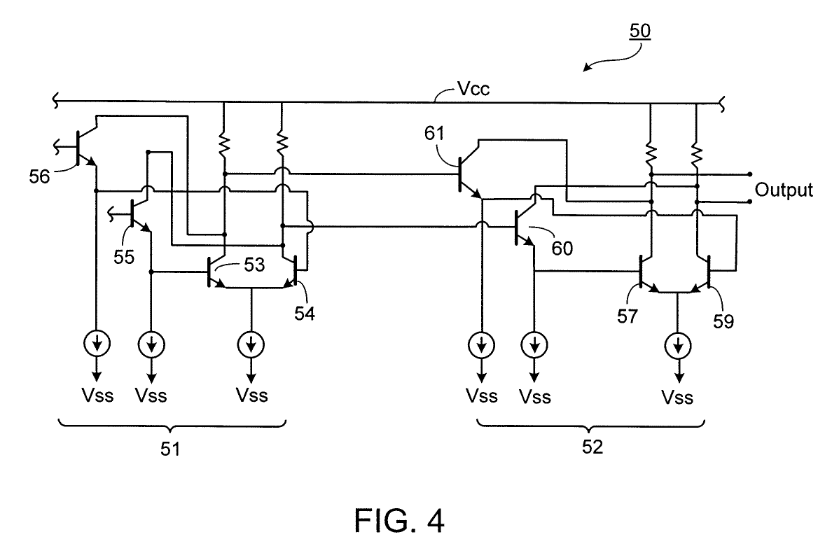

Several differential pair circuits may be combined in stages to form an adjustable delay circuit. In this case, the buffer transistors—e.g., the third and fourth transistors of FIG. 1—may be used to perform interstage level shift functions. FIG. 4 shows an example of an adjustable delay circuit 50 configured by chaining two differential pair circuits of the type shown in FIG. 1. Referring to FIGS. 1 and 4, in first stage 51, transistor 53 corresponds to first transistor 11, transistor 54 corresponds to second transistor 12, transistor 55 corresponds to third transistor 20, and transistor 56 corresponds to fourth transistor 26. In second stage 52, transistor 57 corresponds to first transistor 11, transistor 59 corresponds to second transistor 12, transistor 60 corresponds to third transistor 20, and transistor 61 corresponds to fourth transistor 26. Although only two stages are shown in FIG. 4, additional stages, e.g., three, four, or more, may be added.

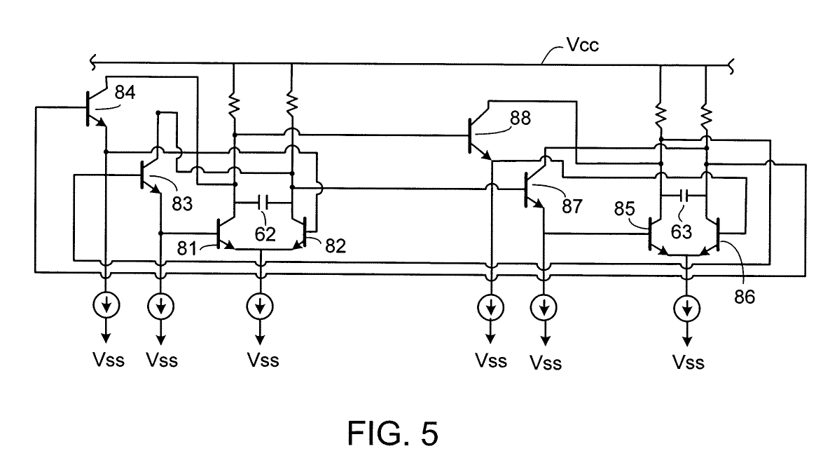

Several differential pair circuits may be combined in stages to form a variable frequency or ring oscillator. For example, capacitors 62, 63 and/or varactors (not shown) may be incorporated into the adjustable delay circuit of FIG. 4—as shown in FIG. 5—to form a variable frequency or ring oscillator. Referring to FIGS. 1 and 5, in the first stage, transistor 81 corresponds to first transistor 11, transistor 82 corresponds to second transistor 12, transistor 83 corresponds to third transistor 20, and transistor 84 corresponds to fourth transistor 26. In the second stage, transistor 85 corresponds to first transistor 11, transistor 86 corresponds to second transistor 12, transistor 87 corresponds to third transistor 20, and transistor 86 corresponds to fourth transistor 26. Although only two stages are shown in FIG. 5, additional stages, e.g., three, four, or more, may be added.

In operation, the oscillator of FIG. 1 outputs a logic one value at one end, feeds that value back to the other end, which results in a logic zero output. The logic zero output is fed back to produce a logic one output, and so on. A buffer may be connected to tap an output of the circuit of FIG. 4.

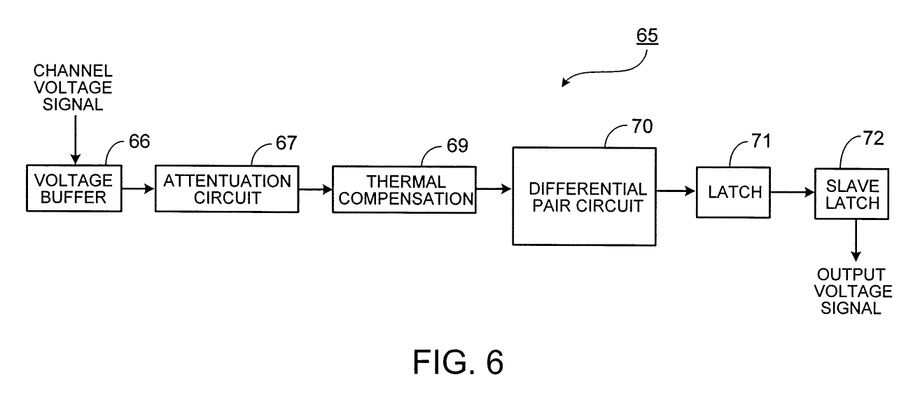

The differential pair circuit described herein may be used in a comparator. A block diagram of a comparator that may incorporate the differential pair circuit is shown in FIG. 6. In one example, comparator 65 may include a voltage buffer 66, an attenuation circuit 67, a thermal compensation circuit 69, a differential pair circuit 70, a latch 71, and a slave latch 72. One or more of these elements may be omitted. Voltage buffer 66 provides a relatively high input resistance, drives the attenuation circuit, and maintains a relatively high degree of accuracy for all input signals to the comparator. Attenuator circuit 67 may be, e.g., a resistive voltage divider between an input signal and a reference voltage, which reduces (e.g., divides-down) input voltages.

Differential pair circuit 70 may be the circuit of FIG. 1. Resistive elements may be included on the first and second collector inputs between the collectors and the reference voltage, here V_{cc}. The output of the differential pair—e.g., at second collector 12b—is a differential signal, which may be the difference between two input signals. Thermal compensation circuit 69 may include emitter followers placed in series with the differential pair circuit, which may have a change in power that is opposite to that of the differential pair. In this regard, transistors 20 and 26 may act as a thermal compensation circuit. The emitter followers may have the same size so that they have the same thermal time constants and, because the collectors of the emitter followers can have any voltage, the voltage is varied at their collectors to control the power of the differential pair.

Latch 71 may be constructed from differential latching transistors, and is used to latch the output of differential pair circuit 70. Slave latch 72 has a transparent state and a latched state. The slave latch is transparent when latch 71 is active (high) and latches when latch 71 is transparent (low). The end result is, therefore, a latched signal timed in accordance with a signal's last rising edge. It is noted that this configuration is designed for 2 GHz logic, and may be different for other types of logic.

The differential pair circuit described herein may be incorporated into any type of comparator, and is not limited to use with the comparator configuration of FIG. 6. In fact, the differential pair circuit of FIG. 1 may function as a comparator itself and may or may not include resistive elements (e.g., resistors) on the first and second collector inputs between the collectors and the reference voltage V_{cc}.

The differential pair circuit described herein may be incorporated into a comparator on automatic test equipment (ATE). For example, the comparator may be incorporated into a receive or “capture” channel of the ATE, as described below.

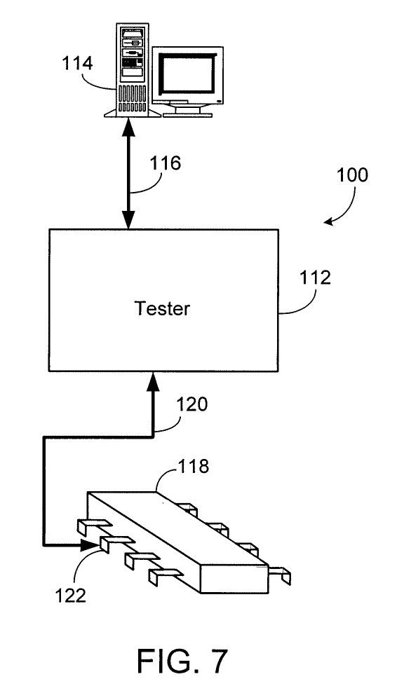

Referring to FIG. 7, an ATE system 100 for testing a device-under-test (DUT) 118, such as a semiconductor device, includes a tester 112. To control tester 112, system 100 includes a computer system 114 that interfaces with tester 112 over a hardwire connection 116. Typically, computer system 114 sends commands to tester 112 to initiate execution of routines and functions for testing DUT 118. Such executing test routines may initiate the generation and transmission of test signals to the DUT 118 and collect responses from the DUT. Various types of DUTs may be tested by system 100. For example, DUTs may be semiconductor devices such as an integrated circuit (IC) chip (e.g., memory chip, microprocessor, analog-to-digital converter, digital-to-analog converter, etc.).

To provide test signals and collect responses from the DUT, tester 112 is connected to one or more connector pins that provide an interface for the internal circuitry of DUT 118. To test some DUTs, e.g., as many as sixty-four or one hundred twenty-eight connector pins (or more) may be interfaced to tester 112. For illustrative purposes, in this example, semiconductor device tester 112 is connected to one connector pin of DUT 118 via a hardwire connection. A conductor 120 (e.g., cable) is connected to pin 122 and is used to deliver test signals (e.g., PMU DC test signals, PE AC test signals, etc.) to the internal circuitry of DUT 118. Conductor 120 also senses signals at pin 122 in response to the test signals provided by semiconductor device tester 112. For example, a voltage signal or a current signal may be sensed at pin 122 in response to a test signal and sent over conductor 120 to tester 112 for analysis. Such single port tests may also be performed on other pins included in DUT 18. For example, tester 112 may provide test signals to other pins and collect associated signals reflected back over conductors (that deliver the provided signals). By collecting the reflected signals, the input impedance of the pins may be characterized along with other single port testing quantities. In other test scenarios, a digital signal may be sent over conductor 120 to pin 122 for storing a digital value on DUT 118. Once stored, DUT 118 may be accessed to retrieve and send the stored digital value over conductor 120 to tester 112. The retrieved digital value may then be identified to determine if the proper value was stored on DUT 118.

Along with performing one-port measurements, a two-port test may also be performed by semiconductor device tester 112. For example, a test signal may be injected over conductor 120 into pin 122 and a response signal may be collected from one or more other pins of DUT 118. This response signal is provided to semiconductor device tester 112 to determine quantities, such as gain response, phase response, and other throughput measurement quantities.

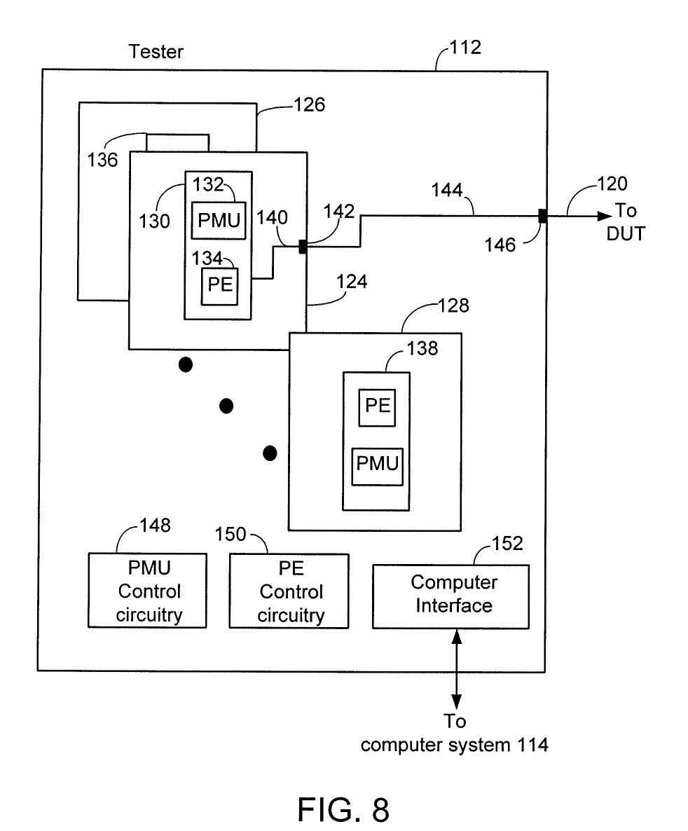

Referring also to FIG. 8, to send and collect test signals from multiple connector pins of a DUT (or multiple DUTs), semiconductor device tester 112 includes an interface card 124 that can communicate with numerous pins. For example, interface card 124 may transmit test signals to, e.g., 32, 64, or 128 pins and collect corresponding responses. Each communication link to a pin is typically referred to as a channel and, by providing test signals to a large number of channels, testing time is reduced since multiple tests may be performed simultaneously. Along with having many channels on an interface card, by including multiple interface cards in tester 112, the overall number of channels increases, thereby further reducing testing time. In this example, two additional interface cards 126 and 128 are shown to demonstrate that multiple interface cards may populate tester 112.

Each interface card includes a dedicated integrated circuit (IC) chip (e.g., an application specific integrated circuit (ASIC)) for performing particular test functions. For example, interface card 124 includes IC chip 130 for performing parametric measurement unit (PMU) tests and pin electronics (PE) tests. IC chip 130 has a PMU stage 132 that includes circuitry for performing PMU tests and a PE stage 134 that includes circuitry for performing PE tests. Additionally, interface cards 126 and 128 respectively include IC chips 136 and 138 that include PMU and PE circuitry. Typically, PMU testing involves providing a DC voltage or current signal to the DUT to determine such quantities as input and output impedance, current leakage, and other types of DC performance characterizations. PE testing involves sending AC test signals, or waveforms, to a DUT (e.g., DUT 118) and collecting responses to further characterize the performance of the DUT. The responses may be collected and compared to predefined, or other, values in order to determine whether the DUT is operating properly. A comparator constructed using the differential pair circuit of FIG. 1 (e.g., the comparator of FIG. 6) may be part of the PE (or PMU) circuitry, and may used to perform the comparison. In one example, IC chip 130 may transmit (to the DUT) AC test signals that represent a vector of binary values for storage on the DUT. Once these binary values have been stored, the DUT may be accessed by tester 112 to determine if the correct binary values have been stored. A comparator, which includes the differential pair circuit, may compare the stored binary values to the transmitted binary values to determine if the correct binary values have been store. Since digital signals typically include abrupt voltage transitions, the circuitry in PE stage 134 on IC chip 130 operates at a relatively high speed in comparison to the circuitry in PMU stage 132.

To pass both DC and AC test signals from interface card 124 to DUT 118, a conducting trace 140 connects IC chip 130 to an interface board connector 142 that allows signals to be passed on and off interface board 124. Interface board connector 142 is also connected to a conductor 144 that is connected to an interface connector 146, which allows signals to be passed to and from tester 112. In this example, conductor 120 is connected to interface connector 146 for bi-directional signal passage between tester 112 and pin 122 of DUT 118. In some arrangements, an interface device may be used to connect one or more conductors from tester 112 to the DUT. For example, the DUT (e.g., DUT 118) may be mounted onto a device interface board (DIB) for providing access to each DUT pin. In such an arrangement, conductor 120 may be connected to the DIB for placing test signals on the appropriate pin(s) (e.g., pin 122) of the DUT.

In this example, only conducting trace 140 and conductor 144 respectively connect IC chip 130 and interface board 124 for delivering and collecting signals. However, IC chip 130 (along with IC chips 136 and 138) typically has multiple pins (e.g., eight, sixteen, etc.) that are respectively connected with multiple conducting traces and corresponding conductors for providing and collecting signals from the DUT (via a DIB). Additionally, in some arrangements, tester 112 may connect to two or more DIB's for interfacing the channels provided by interface cards 124, 126, and 128 to one or multiple devices under test.

To initiate and control the testing performed by interface cards 124, 126, and 128, tester 112 includes PMU control circuitry 148 and PE control circuitry 150 that provide test parameters (e.g., test signal voltage level, test signal current level, digital values, etc.) for producing test signals and analyzing DUT responses. The PMU control circuitry and PE control circuitry may be implemented using one or more processing devices. Examples of processing devices include, but are not limited to, a microprocessor, a microcontroller, programmable logic (e.g., a field-programmable gate array), and/or combination(s) thereof. Tester 112 also includes a computer interface 152 that allows computer system 114 to control the operations executed by tester 112 and also allows data (e.g., test parameters, DUT responses, etc.) to pass between tester 112 and computer system 114.

The ATE described herein is not limited to use with the hardware and software described above. The ATE described herein can be implemented using any hardware and/or software. For example, the ATE described herein, or portion(s) thereof, can be implemented, at least in part, using digital electronic circuitry, or in computer hardware, firmware, software, or in combinations thereof.

The ATE described herein (e.g., the functions performed by the processing device) can be implemented, at least in part, via a computer program product, i.e., a computer program tangibly embodied in an information carrier, e.g., in a one or more machine-readable media or in a propagated signal, for execution by, or to control the operation of, data processing apparatus, e.g., a programmable processor, a computer, or multiple computers. A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a communication network.

Actions associated with implementing the ATE can be performed by one or more programmable processors executing one or more computer programs to perform the functions of the ATE described herein. All or part of the ATE can be implemented as special purpose logic circuitry, e.g., an FPGA (field programmable gate array) and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. Elements of a computer include a processor for executing instructions and one or more memory devices for storing instructions and data.

It is noted that the differential pair circuit described herein has been implemented using NPN transistors. However, the differential pair circuit may also be implemented using PNP transistors or a combination of NPN and PNP transistors. Furthermore, the differential pair circuit described herein has been implemented using BJTs. However, the differential pair circuit may also be implemented using FETs (field effect transistors) or a combination of BJTs and FETs. A FET includes gate, source, and drain terminals, which correspond, respectively, to the base, collector, and emitter terminals of a BJT. That is, the base and gate constitute control terminals, the collector and source constitute input terminals, and the emitter and drain terminals constitute output terminals.

Elements of different embodiments described herein may be combined to form other embodiments not specifically set forth above. Other embodiments not specifically described herein are also within the scope of the following claims.

What is claimed is:

1. A differential pair circuit comprising:
a first transistor having a first control terminal, a first input terminal, and a first output terminal;
a second transistor having a second control terminal, a second input terminal, and a second output terminal,
a first buffer stage comprising a third transistor having a third control terminal, a third input terminal, and a third output terminal;
a second buffer stage comprising a fourth transistor having a fourth control terminal, a fourth input terminal, and a fourth output terminal;
wherein the first output terminal and the second output terminal are electrically connected;
wherein the third output terminal and the first control terminal are electrically connected;
wherein the fourth output terminal and the second control terminal are electrically connected;
wherein the first input terminal and the fourth input terminal are electrically connected; and
wherein the second input terminal and the third input terminal are electrically connected.

2. The differential pair circuit of claim 1, further comprising:
one or more circuit elements electrically connected between the first input terminal and the second input terminal.

3. The differential pair circuit of claim 1, further comprising:
a capacitor electrically connected between the first input terminal and the second input terminal.

4. The differential pair circuit of claim 3, wherein the capacitor has a capacitance that is adjustable.

5. The differential pair circuit of claim 1, further comprising a first current source electrically connected to the third output terminal, a second current source electrically connected to the fourth output terminal, and a third current source electrically connected to both the first output terminal and the second output terminal.

6. The differential pair circuit of claim 1, further comprising:
a first source to apply a first signal to the third control terminal; and
a second source to apply a second signal the fourth control terminal.

7. The differential pair circuit of claim 6, wherein the first and second signals comprise differential signals.

8. The differential pair circuit of claim 6, wherein the first and second signals comprise a differential signal and a reference signal.

9. The differential pair circuit of claim 1, wherein the first transistor has a first control terminal-output terminal capacitance, and the second transistor has a second control terminal-output terminal capacitance;
wherein, when the first transistor is on and the second transistor is off, the first control terminal-output terminal capacitance is larger than the second control terminal-output terminal capacitance; and
wherein, when the first transistor is off and the second transistor is on, the second control terminal-output terminal capacitance is larger than the first control terminal-output terminal capacitance.

10. The differential pair circuit of claim 1, further comprising:
at least one reference voltage electrically connected to the first input terminal and to the second input terminal.

11. The differential pair circuit of claim 1, further comprising:
one or more varactors electrically connected between the first input terminal and the second input terminal.

12. Circuitry comprising:
a first differential pair circuit; and
a second differential pair circuit electrically connected to the first differential pair circuit;
wherein the first differential pair circuit comprises:
a first transistor having a first control terminal, a first input terminal, and a first output terminal;
a second transistor having a second control terminal, a second input terminal, and a second output terminal;
a third transistor having a third control terminal, a third input terminal, and a third output terminal;
a fourth transistor having a fourth control terminal, a fourth input terminal, and a fourth output terminal;
wherein the first output terminal and the second output terminal are electrically connected;
wherein the third output terminal and the first control terminal are electrically connected;
wherein the fourth output terminal and the second control terminal are electrically connected;
wherein the first input terminal and the fourth input terminal are electrically connected; and
wherein the second input terminal and the third input terminal are electrically connected; and
wherein the second differential pair circuit comprises:
a fifth transistor having a fifth control terminal, a fifth input terminal, and a fifth output terminal;
a sixth transistor having a sixth control terminal, as sixth input terminal, and a sixth output terminal,
a seventh transistor having a seventh control terminal, a seventh input terminal, and a seventh output terminal;
an eighth transistor having an eighth control terminal, an eighth input terminal, and an eighth output terminal;
wherein the fifth output terminal and the sixth output terminal are electrically connected;
wherein the seventh output terminal and the fifth control terminal are electrically connected;
wherein the eighth output terminal and the sixth control terminal are electrically connected;
wherein the fifth input terminal and the eighth input terminal are electrically connected; and
wherein the sixth input terminal and the seventh input terminal are electrically connected.

13. The circuitry of claim 12, wherein the first input terminal and the eighth control terminal are electrically connected; and
wherein the second input terminal and the seventh control terminal are electrically connected.

14. The circuitry of claim 12, further comprising:
a first capacitor electrically connected between the first input terminal and the second input terminal; and
a second capacitor electrically connected between the fifth input terminal and the sixth input terminal.

15. The circuitry of claim 14, wherein at least one of the first capacitor and the second capacitor has a capacitance that is adjustable.

16. The circuitry of claim 12, further comprising:
a first set of one or more varactors electrically connected between the first input terminal and the second input terminal; and
a second set of one or more varactors electrically connected between the fifth input terminal and the sixth input terminal.

17. A comparator comprising:
an output terminal; and
a differential pair for comparing a first signal to a second signal to generate an output signal at the output terminal, the differential pair comprising:
a first transistor having a first control terminal, a first input terminal, and a first output terminal;
a second transistor having a second control terminal, a second input terminal, and a second output terminal;
a third transistor having a third control terminal, a third input terminal, and a third output terminal;
a fourth transistor having a fourth control terminal, a fourth input terminal, and a fourth output terminal;
wherein the first output terminal and the second output terminal are electrically connected;
wherein the third output terminal and the first control terminal are electrically connected;
wherein the fourth output terminal and the second control terminal are electrically connected;
wherein the first input terminal and the fourth input terminal are electrically connected; and
wherein the second input terminal and the third input terminal are electrically connected;
wherein the first signal is applied to the third control terminal; and
wherein the second signal is applied to the fourth control terminal.

18. The comparator of claim 17, further comprising:
a voltage buffer for receiving a first signal and for storing the first signal.

19. The comparator of claim 18, further comprising:
an attenuator for attenuating the first signal following output from the voltage buffer and prior to application to the one of the third control terminal and the fourth control terminal.

20. Automatic test equipment comprising:
circuitry to generate test signals to send to a device under test (DUT); and
a comparator comprising the differential pair circuit of claim 1 configured to receive responses from the DUT to the test signals, and to compare the responses to one or more values in order to determine a state of operation of the DUT.
